(19) United States
(12) Patent Application Publication
(10) Pub. No.: US 2006/0163482 A1
(43) Pub. Date: Jul. 27, 2006

(54) Pyroelectric sensor and method for determining a temperature of a portion of a scene utilizing the pyroelectric sensor

(76) Inventor: Joseph V. Mantese, Shelby Twp., MI (US)

Correspondence Address: DELPHI TECHNOLOGIES, INC., M/C 480-410-202, PO BOX 5052, TROY, MI, 48007, US

(21) Appl. No.: 11/319,033

(22) Filed: Dec. 27, 2005

Related U.S. Application Data
(60) Provisional application No. 60/639,467, filed on Dec. 28, 2004.

(51) Int. Cl. H01L 37/00; G01J 5/12

(52) U.S. Cl. 250/338.2; 250/338.3

(57) ABSTRACT

A pyroelectric sensor and a method for determining a scene temperature are provided. The pyroelectric sensor includes a ferroelectric layer having first and second sides. The pyroelectric sensor further includes a first metal electrode disposed on the first side of the ferroelectric layer. The pyroelectric sensor further includes a second metal electrode disposed on the first side of the ferroelectric layer a predetermined distance from the first metal electrode. When a switching voltage is applied to between the first and second metal electrodes so as to switch a polarization state of the ferroelectric layer, an amount of current flowing between the first and second metal electrodes is indicative of a temperature level of the ferroelectric layer.

### CROSS REFERENCE TO RELATED APPLICATION

The application claims the benefit of U.S. Provisional application Ser. No. 60/639,467, filed Dec. 28, 2004, the contents of which are incorporated herein by reference thereto.

### TECHNICAL FIELD

This application relates to a pyroelectric sensor and a method for determining a temperature of a portion of a scene utilizing the pyroelectric sensor.

### BACKGROUND

Focal plane arrays have been developed that utilize a plurality of ferroelectric sensors. Each ferroelectric sensor generates an electrical charge based upon a temperature of the ferroelectric sensor. The ferroelectric sensor is constructed in a vertical stacked arrangement including (i) a ferroelectric material, (ii) a top conductive layer disposed on a top surface of the ferroelectric material, and (iii) a bottom conductive layer disposed on a bottom surface of the ferroelectric material. A problem associated with the ferroelectric sensor having the vertical stacked arrangement is that the sensor has a relatively large thermal mass resulting in a response time that is slower than a desired response time. Further, a multi-step fabrication process is required for manufacturing the ferroelectric sensor that is relatively labor-intensive and expensive. Further, the multi-step fabrication process limits the type of metal that can be used for the top and bottom conductive layers to platinum.

Accordingly, there is a need for an improved ferroelectric sensor which minimizes or eliminates the above-identified deficiencies.

### SUMMARY

A pyroelectric sensor in accordance with an exemplary embodiment is provided. The pyroelectric sensor includes a ferroelectric layer having first and second sides. The pyroelectric sensor further includes a first metal electrode disposed on the first side of the ferroelectric layer. The pyroelectric sensor further includes a second metal electrode is also disposed on the first side of the ferroelectric layer a predetermined distance from the first metal electrode. When a switching voltage is applied between the first and second metal electrodes so as to switch a polarization state of the ferroelectric layer, an amount of switching current flowing between the first and second metal electrodes is indicative of a temperature level of the ferroelectric layer. In another exemplary embodiment, a focal plane array is provided. The focal plane array comprising: a plurality of pyroelectric sensors, each pyroelectric sensor comprising: a ferroelectric layer having first and second sides; a first metal electrode disposed on the first side of the ferroelectric layer; and a second metal electrode disposed on the first side of the ferroelectric layer a predetermined distance from the first metal electrode, wherein when a switching voltage is applied between the first and second metal electrodes so as to switch a polarization state of the ferroelectric layer, an amount of switching current flowing between the first and second metal electrodes is indicative of a temperature level of the ferroelectric layer.

A method for determining a temperature of a portion of a scene utilizing a pyroelectric sensor in accordance with another exemplary embodiment is provided. The pyroelectric sensor has a ferroelectric layer, and first and second metal electrodes. The ferroelectric layer has first and second sides. The first metal electrode is disposed on the first side of the ferroelectric layer. The second metal electrode is also disposed on the first side of the ferroelectric layer a predetermined distance from the first metal electrode. The method includes applying a switching voltage between the first and second metal electrodes disposed on the first side of the ferroelectric layer so as to switch a polarization state of the ferroelectric layer. The method further includes measuring an amount of switching current flowing between the first and second metal electrodes that is indicative of a temperature level of the ferroelectric layer.

### BRIEF DESCRIPTION OF THE DRAWINGS

FIG. 1 is a block diagram of a system for controlling a focal plane array;

FIG. 2 is a top view of the focal plane array of FIG. 1;

FIG. 3 is a schematic of an oscillatory voltage waveform utilized in the system of FIG. 1;

FIG. 4 is a schematic of a pyroelectric sensor that is utilized in the focal plane array of FIG. 2 in accordance with an exemplary embodiment;

FIG. 5 is a top view of a pyroelectric sensor can be utilized in the focal plane array of FIG. 2 in accordance with another exemplary embodiment; and

FIG. 6 is a top view of a pyroelectric sensor can be utilized in the focal plane array of FIG. 2 in accordance with another exemplary embodiment.

### DESCRIPTION OF EXEMPLARY EMBODIMENTS

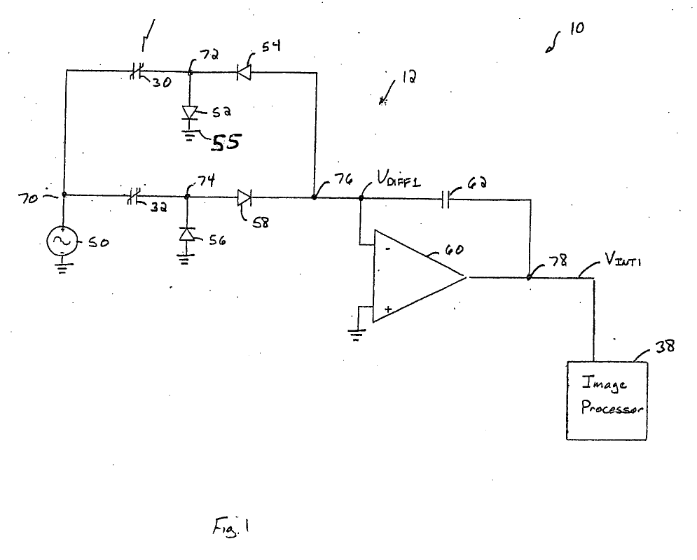

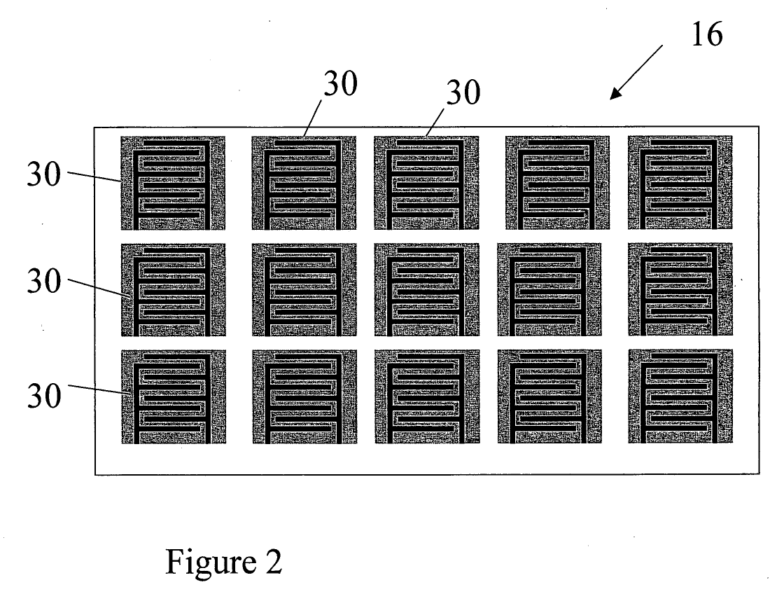

Referring to FIGS. 1 and 2, a system 10 for controlling pyroelectric sensors in the focal plane array 16 is illustrated. The system 10 includes an electrical circuit 12, a focal plane array 16, and an image processor 38. The focal plane array 16 comprises a plurality of pyroelectric sensors including sensor 30. Although only one sensor 30 is shown in FIG. 1, a plurality of sensors 30 comprising a focal plane array may be provided in accordance with exemplary embodiments of the present invention (FIG. 2). Each of the pyroelectric sensors in the focal plane array 16 exposed to infrared light generates a signal indicative of a temperature of a portion of an image scene that is detected by the pyroelectric sensors.

The electric circuit 12 is provided to switch the pyroelectric sensors 30, 32 between first and second polarization states such that the circuit 12 generates a differential signal indicative of a temperature of the sensor 30. The electric circuit 12 includes a voltage source 50, the pyroelectric sensors 30, 32, diodes 52, 54, 56, 58, an operational amplifier 60, and a capacitor 62. The voltage source 50 is electrically coupled to the pyroelectric sensors 30, 32 at the node 70. The pyroelectric sensor 30 is further electrically coupled to the node 72. The diode 52 has an anode electrically coupled to the node 72 and a cathode electrically coupled to a system ground 55. The diode 54 has an anode electrically coupled to a node 76 and a cathode electrically coupled to the node 72. Further, the pyroelectric sensor 32 is electrically coupled to the node 74. Further, the diode 56 has a cathode electrically coupled to the node 74 and an anode electrically coupled to the system ground 55. The diode 58 has an anode electrically coupled to the node 74 and a cathode electrically coupled to the node 76. Still further, the operational amplifier 60 includes a non-inverting terminal, an inverting terminal, and an output terminal. The non-inverting terminal of the operational amplifier 60 is electrically coupled to system ground 55. The inverting terminal of the operational amplifier 60 is electrically coupled to the node 76. The capacitor 62 is electrically coupled between the nodes 76, 78 and the node 78 is further electrically coupled to the output terminal of the operational amplifier 60. Finally, the node 78 is electrically coupled to the image processor 38.

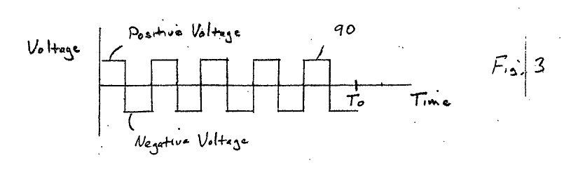

Referring to FIGS. 1 and 3, the voltage source 50 is provided to generate an oscillatory voltage waveform 90, also known as a switching voltage waveform, that is transmitted to the pyroelectric electric sensors 30, 32. The oscillatory voltage waveform 90 comprises a pulse-width modulated voltage waveform. It should be noted, however, that in an alternative embodiment, the oscillatory voltage waveform can comprise any oscillating voltage waveform, known to those skilled in the art. For example, the oscillatory voltage waveform can comprise an AC voltage waveform, a triangular-shaped voltage waveform, and a sawtooth-shaped voltage waveform. When the waveform 90 has a positive voltage, the polarization states of the pyroelectric sensors 30, 32 are switched toward a first polarization state and when the waveform 90 has a negative voltage, the polarization is switched toward a second polarization state.

The pyroelectric sensors 30, 32 of the focal plane array 16 are provided to generate output voltages that will be utilized by the circuit 12 to generate output signal (Vᵢₙₜ₁) indicating an average temperature of the pyroelectric sensor 30. The pyroelectric sensor 30 is exposed to infrared radiation from a portion of physical environment. The pyroelectric sensor 32 is not exposed to any incoming infrared radiation, and generates a reference charge Q_{Reference1}. When a temperature of the pyroelectric sensor 30 is greater than a temperature of the sensor 32, the polarization of the pyroelectric sensor 30 is less than a polarization of the pyroelectric sensor 32. Further, an amount of electrical charge generated by the pyroelectric sensor 30 is less than an amount of electrical charge generated by the pyroelectric sensor 32. Alternatively, when a temperature of the pyroelectric sensor 30 is less than a temperature of the sensor 32, the polarization of the pyroelectric sensor 30 is greater than a polarization of the pyroelectric sensor 32. Further, an amount of electrical charge generated by the pyroelectric sensor 30 is less than an amount of electrical charge generated by the pyroelectric sensor 32.

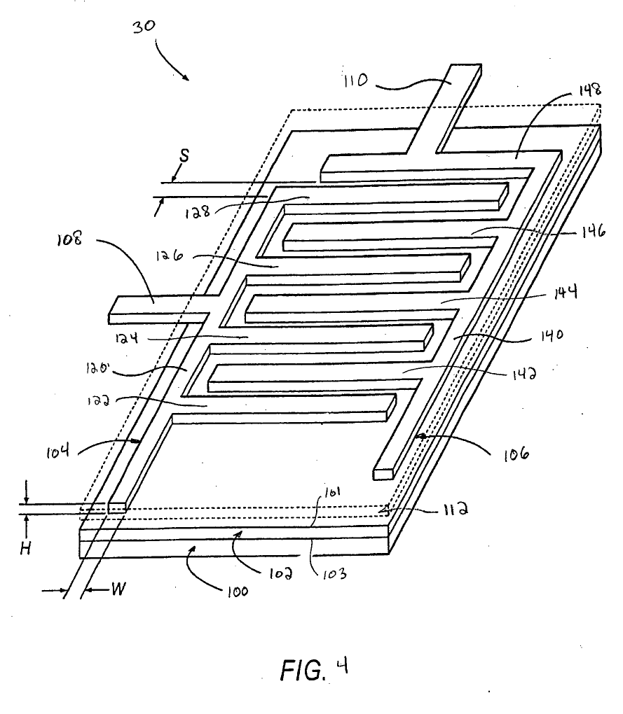

Referring to FIG. 4, a structure of the pyroelectric sensor 30 will now be explained. It should be noted that the structure of the pyroelectric sensor 32 has a substantially similar structure as the pyroelectric sensor 30. Accordingly, only the structure of the pyroelectric sensor 30 will be explained in detail. The pyroelectric sensor 30 includes an insulation layer 100, a ferroelectric layer 102, electrodes 104, 106, electrical terminals 108, 110, and a heat absorbing layer 112 tuned to the waveband of the radiation of interest (e.g., light to be detected).

The insulation layer 100 is provided to insulate the remaining components of the pyroelectric sensor 30. The insulation layer 100 comprises a substantially planar insulation layer constructed from silicon dioxide.

The ferroelectric layer 102 is constructed from a ferroelectric material strontium bismuth tantalate (SBT) (SrBi2Ta209). However, in alternative embodiments other ferroelectric materials or the like can be utilized for the ferroelectric layer 102. The ferroelectric layer 102 includes a side 101 and a side 103 opposite the side 101. The ferroelectric layer 102 is disposed on side 103 to the insulation layer 102. In one exemplary embodiment, the dielectric constant of the ferroelectric layer 102 is approximately equal to one-hundred nanometers.

The electrodes 104 and 106 are disposed on the side 101 of the ferroelectric layer 102. The electrodes 104 and 106 are spaced apart from one another and are provided to form a plurality of dipole moments therebetween when a switching voltage is applied between the electrodes 104 and 106. The electrodes 104 and 106 are constructed from a metal, such as copper, aluminum, titanium, platinum, or alloys thereof for example.

The electrode 104 includes a base portion 120 and extension portions 122, 124, 126, and 128. The extension portions 122, 124, 126, and 128 extend from the base portion 120 generally perpendicular to the base portion 120. Each of the extension portions 122, 124, 126, and 128 are disposed substantially parallel to one another. In an exemplary embodiment, the base portion 120 and the extension portions 122, 124, 126, and 128 have a height (H) in a range of 0.001-10 micrometers. Of course, in alternative embodiments the base portion 120 and the extension portions 122, 124, 126, and 128 can have a height less than 0.001 micrometers or greater than 10 micrometers. Further, in the exemplary embodiment, the base portion 120 and the extension portions 122, 124, 126, and 128 have a width (W) in a range of 0.001-100 micrometers. Of course, in alternative embodiments in the base portion 120 and the extension portions 122, 124, 126, and 128 can have a width less than 0.001 micrometers or greater than 100 micrometers.

The electrode 106 includes a base portion 140 and extension portions 142, 144, 146 and 148. The extension portions 142, 144, 146 and 148 extend from the base portion 140 generally perpendicular to the base portion 140 toward the base portion 120. Each of the extension portions 142, 144, 146 and 148 are disposed substantially parallel to one another. The extension portion 142 is disposed in a region between the extension portions 122 and 124. The extension portion 144 is disposed in a region between the extension portions 124 and 126. Further, the extension portion of 146 is disposed in a region between the extension portions 126 and 128. Still further, the extension portion 128 is disposed in a region between the extension portions 146 and 148. In an exemplary embodiment, the base portion 140 and the extension portions 142, 144, 146 and 148 have a height (H) in a range of 0.001-10 micrometers. Of course, in alternative embodiments in the base portion 140 and the extension portions 142, 144, 146 and 148 can have a height less than 0.001 micrometers or greater than 10 micrometers. Further, in the exemplary embodiment, the base portion 140 and the extension portions 142, 144, 146 and 148 have a width (W) in a range of 0.001-100 micrometers. Of course, in alternative embodiments in the base portion 140 and the extension portions 142, 144, 146 and 148 can have a width less than 0.001 micrometers or greater than 100 micrometers.

In the exemplary embodiment, the spacing (S) between adjacent extension portions of the electrodes 104 and 106 is in a range of 0.001-100 micrometers. Of course in alternative embodiments, the spacing (S) can be less than 0.001 micrometers or greater than 100 micrometers.

When a switching voltage is applied between the electrodes 104 and 106, a first electric field (not shown) travels through the ferroelectric layer 102 between adjacent extension portions of the electrodes 104 and 106. Further, a second electric field, which is a parasitic by-product field, travels between the spacing (S) between adjacent extension portions of the electrodes 104 and 106. The dielectric constant of the air is approximately equal to one. An electrical current that flows between the electrodes 104 and 106 is indicative of a temperature level of the ferroelectric layer 102, which is further indicative of a portion of the scene of the environment being sensed by the pyroelectric sensor 30.

The electrical terminals 108, 110 are electrically coupled to the electrodes 104, 106, respectively and are provided to apply a voltage to the electrodes 104, 106. In one exemplary embodiment, the electrical terminal 108 is electrically coupled to the node 70 and the terminal 110 is electrically coupled to the node 72.

The heat absorbing layer 112 is provided to absorb heat energy from visible light and infrared light reflected from a portion of a scene of an environment onto the heat absorbing layer 112. The heat absorbing layer 112 is disposed over the electrodes 104 and 106 and portions of the ferroelectric layer 102 not covered by the electrodes 104 and 106. In one non-limiting exemplary embodiment, heat absorbing layer 112 comprises a silicon dioxide with a thin layer of platinum wherein the heat absorbing layer is tuned to allow radiation or light of interest therethrough. Of course, other materials comprising heat absorbing layer 112 are considered to be within the scope of exemplary embodiments of the present invention. Non-limiting examples of desirable wavebands are 3-5 microns and 8-12 microns. Of course, wavebands greater or less than the aforementioned ranges are considered to be within the scope of exemplary embodiments of the present invention.

In accordance with an exemplary embodiment the pyroelectric sensor is constructed to have a planar configuration providing a lower profile than sensors with electrodes stacked upon each other. In one non-limiting exemplary embodiment, insulation layer 100 and ferroelectric layer 102 are planar members and electrodes 104 and 106 are disposed upon the side of the ferroelectric layer opposite the insulation layer using lithographic fabrication techniques, lithography, silk screening or equivalents thereof resulting in a substantially low profile. Thereafter, heat absorbing layer 112 is disposed upon electrodes 104 and 106.

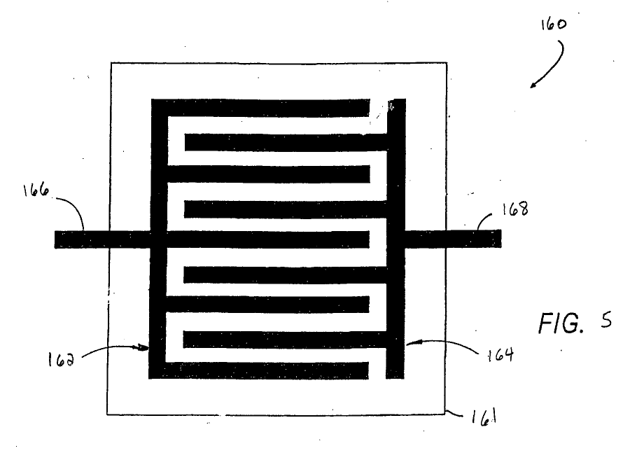

Referring to FIG. 5, a pyroelectric sensor 160 in accordance with another exemplary embodiment is illustrated. The pyroelectric sensor 160 can be utilized in the focal plane array 16, instead of the pyroelectric sensor 30. The primary difference between the pyroelectric sensor 160 and the pyroelectric sensor 30 is the positioning of electrodes coupled thereto. The pyroelectric sensor 160 includes a ferroelectric layer 161 disposed on an insulation layer (not shown). The pyroelectric sensor 160 further includes electrodes 162 and 164 disposed on the ferroelectric layer 161. The electrodes 160 and 164 are constructed from a metal, such as copper, aluminum, titanium, platinum, or alloys thereof for example. The pyroelectric sensor 160 further includes electrical terminals 166, 168 electrically coupled to the electrodes 162, 164, respectively where the electrical terminals 166, 168 are disposed substantially parallel to one another. In one exemplary embodiment, the electrical terminals 166, 168 are electrically coupled to the nodes 70, 72, respectively. The pyroelectric sensor 160 further includes a heat absorbing layer (not shown) disposed over the electrodes 162 and 164 and a portion of the ferroelectric layer 161 not covered by the electrodes 162 and 164.

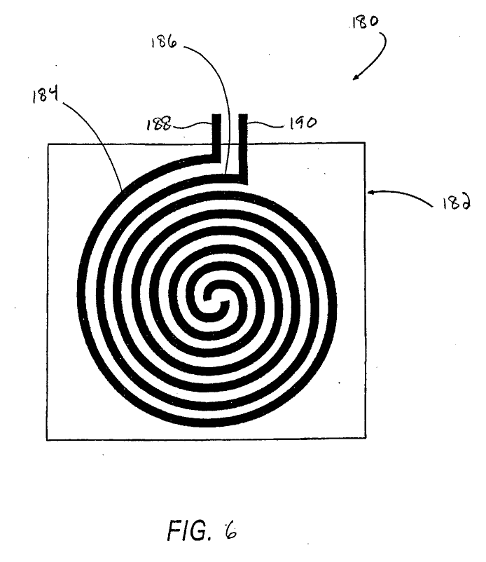

Referring to FIG. 6, a pyroelectric sensor 180 in accordance with another exemplary embodiment is illustrated. The pyroelectric sensor 180 can be utilized in the focal plane array 16, instead of the pyroelectric sensor 30. The primary difference between the pyroelectric sensor 180 and the pyroelectric sensor 30 is the configuration of the electrodes thereof. The pyroelectric sensor 180 includes a ferroelectric layer 182 disposed on a heat absorbing layer (not shown). The pyroelectric sensor 180 further includes electrodes 184 and 186. The electrode 184 has a generally spiral configuration. The electrode 186 also has a generally spiral configuration and is disposed a predetermined distance from the electrode 184 along substantially an entire length of the electrode 186. The pyroelectric sensor 180 further includes electrical terminals 188, 190 electrically coupled to the electrodes 184, 186, respectively where the electrical terminals 188, 190 are disposed substantially parallel to one another. In one exemplary embodiment, the electrical terminals 188, 190 are electrically coupled to the nodes 70, 72, respectively. The pyroelectric sensor 180 further includes insulation layer (not shown) disposed over the electrodes 184 and 186, and a portion of the ferroelectric layer 182 not covered by the electrodes 184 and 186.

Referring to FIGS. 1 and 3, a general overview of the operation of the system 10 will now be provided. When the voltage source 50 transmits an oscillatory voltage waveform 90 to the pyroelectric sensors 30, 32, the pyroelectric sensors 30, 32 switch between a first polarization state and a second polarization state. Each time the pyroelectric sensors 30, 32 switch from an unpoled state, an electrical charge Qₛ₁ is applied from the voltage source 50 to the pyroelectric sensor 30. The electrical charge Qₛ₁ can be calculated using the following equation:
Qₛ₁=A1*Pₛ₁
where:
A1 is the area of the pyroelectric sensor 30;
Pₛ₁ is a change in spontaneous polarization per unit volume of the pyroelectric sensor 30 due to a temperature change ΔTₚ₁. If the positive or negative electrical charge of the pyroelectric sensor 30 is integrated over a predetermined time period, the total charge accumulated for a predetermined number of cycles N1 of the voltage waveform 90, can be calculated utilizing the following equation:
Q_{Total1}=N1*Qₛ₁=N1*A1*Pₛ₁
Further, the total charge Q_{Total1} is indicative of an electrical current level flowing through the pyroelectric sensor 30, which is further indicative of the temperature of the pyroelectric sensor 30, which is further indicative of a temperature of portion of a scene being monitored by the pyroelectric sensor 30.

The electric circuit 12 generates a signal V_{Diff1} on the node 76 in response to the voltage waveform 90 corresponding to a difference between the Q_{Tota11} electrical charge of the pyroelectric sensor 30 and the Q_{Reference1} electrical charge of the pyroelectric sensor 32. The operational amplifier 60 in conjunction with the capacitor 62 integrates the signal V_{Diff1} over a predetermined time period to generate the signal V_{Int1}, that is indicative of an average temperature of the pyroelectric sensor 30. It should be noted that by integrating the signal V_{Diff1} over time, incoherent noise in the signal V_{Diff1} is canceled out and the signal-to-noise ratio of the signal V_{Int1} is greater than the signal V_{Diff1}. In particular, the signal-to-noise ratio of the signal V_{Int1} is increased by N1^{1/2} for random Gaussian noise, as compared to the signal-to-noise ratio of the voltage signal V_{Diff1}, where N1 represents the number of cycles of the voltage waveform 90 applied to the pyroelectric sensor 30.

Further, an active mode effective pyroelectric coefficient P_{eff} for the pyroelectric sensor 30 is defined by the following equation:
P_{eff}=ΔQ1/A1*ΔTₚ₁=N1*ΔPₛ₁/ΔTₚ₁
where:
ΔQ1 is a change in electrical charge of the pyroelectric sensor 30;
A1 is an area of the pyroelectric sensor 30;
ΔTₚ₁ is a change in a temperature of the pyroelectric sensor 30;
N1 is the number of cycles of the voltage signal 90 applied to the pyroelectric sensor 30; and
ΔPₛ₁ is a change in spontaneous polarization per unit volume of the pyroelectric sensor due to a temperature change ΔTₚ₁.

Referring again to FIG. 1, the image processor 38 receives the voltage signal V_{Int1} from the electrical circuit 12 and generates image data based on the signal.

The system 10 has been described above having electrical circuit 12 for controlling pyroelectric sensor 30 for purposes of simplicity. It should be noted, however, that a plurality of additional electrical circuits having a substantially similar structure as circuit 12 would be utilized for controlling additional pyroelectric sensors receiving infrared light in the focal plane array 16. Of course, voltage sources for each of the pyroelectric sensors could vary the number of cycles of a voltage waveform applied to the pyroelectric sensors to adjust the corresponding signal-to-noise ratios and sensitivities.

The inventive pyroelectric sensors and the method for determining a temperature of a portion of the scene provide a substantial advantage over other sensors and methods. In particular, the pyroelectric sensor provides a technical effect of utilizing first and second electrodes disposed on one side of a ferroelectric layer to detect a temperature of the pyroelectric sensor which is indicative of a portion of the scene being monitored by the pyroelectric sensor. As a result, the inventive pyroelectric sensor has a substantially thinner profile and a smaller thermal mass as compared to other pyroelectric sensors. Thus, the pyroelectric sensor has a faster response time than other sensors. Further, the inventive pyroelectric sensor can utilize a plurality of additional metals, such as copper or aluminum for example, for the first and second electrodes, which cannot be utilized with other pyroelectric sensors that require high temperature deposition methods or oxidizing atmospheres.

While embodiments of the invention are described with reference to the exemplary embodiments, it will be understood by those skilled in the art that various changes may be made and equivalence may be substituted for elements thereof without departing from the scope of the invention. In addition, many modifications may be made to the teachings of the invention to adapt to a particular situation without departing from the scope thereof. Therefore, it is intended that the invention not be limited to the embodiment disclosed for carrying out this invention, but that the invention includes all embodiments falling within the scope of the intended claims. Moreover, the use of the term's first, second, etc. does not denote any order of importance, but rather the term's first, second, etc. are used to distinguish one element from another. Furthermore, the use of the terms a, an, etc. do not denote a limitation of quantity, but rather denote the presence of at least one of the referenced items.

What is claimed is:

1. A pyroelectric sensor, comprising:
a ferroelectric layer having first and second sides;
a first metal electrode disposed on the first side of the ferroelectric layer; and
a second metal electrode disposed on the first side of the ferroelectric layer a predetermined distance from the first metal electrode, wherein when a switching voltage is applied between the first and second metal electrodes so as to switch a polarization state of the ferroelectric layer, an amount of switching current flowing between the first and second metal electrodes is indicative of a temperature level of the ferroelectric layer.

2. The pyroelectric sensor of claim 1, further comprising a voltage source electrically coupled to the first and second metal electrodes, the voltage source configured to generate the switching voltage applied between the first and second metal electrodes.

3. The pyroelectric sensor of claim 1, wherein the first metal electrode has a first base portion and at least first and second extension portions extending generally in a first direction from the first base portion, and the second metal electrode having a second base portion and at least third and fourth extension portions extending generally in a second direction from the second base portion toward the first base portion, the second direction being opposite the first direction, the first base portion being disposed substantially parallel to the second base portion.

4. The pyroelectric sensor of claim 1, wherein the first metal electrode has a generally spiral configuration, and the second metal electrode has a generally spiral configuration and is disposed a predetermined distance from the first metal electrode along substantially an entire length of the second metal electrode.

5. The pyroelectric sensor of claim 5, further comprising first and second electrical terminals electrically coupled to the first and second metal electrodes, respectively.

6. The pyroelectric sensor of claim 5, wherein the first and second electrical terminals extend from the first and second metal electrodes, respectively, substantially perpendicular to one another.

7. The pyroelectric sensor of claim 1, wherein the first and second electrical terminals extend from the first and second metal electrodes, respectively, substantially parallel to one another.

8. The pyroelectric sensor of claim 1, wherein the first metal electrode is comprises at least one of a copper electrode, an aluminum electrode, a platinum electrode, and a titanium electrode.

9. The pyroelectric sensor of claim 1, further comprising an insulation layer disposed on the second side of the ferroelectric layer.

10. The pyroelectric sensor of claim 9, wherein the insulation layer comprises a silicon dioxide layer.

11. The pyroelectric sensor of claim 1, further comprising a heat absorbing layer disposed over the first and second metal electrodes and at least a portion of the first side of the ferroelectric layer, wherein the heat absorbing layer is tuned to a particular waveband of light.

12. The pyroelectric sensor of claim 1, wherein the ferroelectric layer is a planar member and the first and second electrodes are printed onto the first side of the ferroelectric layer.

13. The pyroelectric sensor of claim 1, wherein the first metal electrode comprises a first plurality of extension portions extending generally in a first direction, and the second metal electrode comprises a plurality of second extension portions extending generally in a second direction, the second direction being opposite the first direction, wherein the first plurality of extension portions and the second plurality of extension portions are arranged in a spaced inter-leaving manner on the first side of the ferroelectric layer.

14. The pyroelectric sensor of claim 13, further comprising a heat absorbing layer disposed over the first and second metal electrodes and at least a portion of the first side of the ferroelectric layer, wherein the heat absorbing layer is tuned to a particular waveband of light.

15. The pyroelectric sensor of claim 14, further comprising an insulation layer disposed on the second side of the ferroelectric layer.

16. A focal plane array, comprising:
a plurality of pyroelectric sensors, each pyroelectric sensor comprising:
a ferroelectric layer having first and second sides;
a first metal electrode disposed on the first side of the ferroelectric layer; and
a second metal electrode disposed on the first side of the ferroelectric layer a predetermined distance from the first metal electrode, wherein when a switching voltage is applied between the first and second metal electrodes so as to switch a polarization state of the ferroelectric layer, an amount of switching current flowing between the first and second metal electrodes is indicative of a temperature level of the ferroelectric layer.

17. The focal plane array as in claim 16, wherein the array is configured to generate a signal indicative of a temperature of a portion of an image scene that is detected by the plurality of pyroelectric sensors.

18. The focal plane array as in claim 16, wherein the first metal electrode of each of the plurality of pyroelectric sensors comprises a first plurality of extension portions extending generally in a first direction, and the second metal electrode of each of the plurality of pyroelectric sensors comprises a plurality of second extension portions extending generally in a second direction, the second direction being opposite the first direction, wherein the first plurality of extension portions and the second plurality of extension portions are arranged in a spaced inter-leaving manner on the first side of the ferroelectric layer; and each of the plurality of pyroelectric sensors, further comprises a heat absorbing layer disposed over the first and second metal electrodes and at least a portion of the first side of the ferroelectric layer and an insulation layer disposed on the second side of the ferroelectric layer.

19. A method for determining a temperature of a portion of a scene utilizing a pyroelectric sensor, the pyroelectric sensor having a ferroelectric layer, and first and second metal electrodes, the ferroelectric layer having first and second sides, the first metal electrode disposed on the first side of the ferroelectric layer, the second metal electrode disposed on the first side of the ferroelectric layer a predetermined distance from the first metal electrode, the method comprising:
applying a switching voltage between the first and second metal electrodes disposed on the first side of the ferroelectric layer; and
measuring an amount of switching current flowing between the first and second metal electrodes that is indicative of a temperature level of the ferroelectric layer.

20. The method of claim 19, further comprising receiving light reflected from a portion of a scene of an environment onto a heat absorbing layer disposed over at least a portion of the first and second metal electrodes and the ferroelectric layer, wherein the heat absorbing layer is tuned to a particular waveband of light.

21. The method of claim 20, wherein the amount of switching current is further indicative of a temperature level of the portion of the scene.
